(19) United States
(12) Patent Application Publication
(10) Pub. No.: US 2008/0248641 A1
(43) Pub. Date: Oct. 9, 2008

(54) Method of manufacturing semiconductor device

(75) Inventor: Mariko Makabe, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/905,074

(22) Filed: Sep. 27, 2007

(30) Foreign Application Priority Data
Apr. 4, 2007 (JP) 2007-098048

(51) Int. Cl. H01L 21/3205

(52) U.S. Cl. 438/585; 257/E21.294

(57) ABSTRACT

A method of manufacturing a semiconductor device according to this invention includes; forming a first region in which a first insulating film is formed on a semiconductor substrate surface and a second region on which the semiconductor substrate surface is exposed; cleaning the semiconductor substrate surface exposed in the second region with a cleaning fluid; removing a chemical oxide film formed on the semiconductor substrate surface in the second region with the cleaning fluid; forming a second insulating film having a film thickness different from that of the first insulating film on the semiconductor substrate surface in the second region; and forming a gate electrode film on the first insulating film and the second insulating film to form a pattern in the gate electrode film (and the first insulating film and the second insulating film formed under the gate electrode film). In removing the oxide film, the oxide film is removed by processing the semiconductor substrate in the presence of a hydrogen gas at a temperature of not less than 940° and not more than 990° and a pressure of not less than 30 Torr and not more than 150 Torr.

This application is based on Japanese patent application NO. 2007-098048, the content of which is incorporated hereinto by reference.

### BACKGROUND

1. Technical Field

The present invention relates to a method of manufacturing a semiconductor device using a multi-oxide process.

2. Related Art

When an integrated circuit using a plurality of elements is to be constituted, a technique in which transistors of different types are formed on the same substrate is required. For this reason, a technique (multi-oxide process) in which gate insulating films having different film thicknesses are formed on one wafer is proposed.

A conventional multi-oxide process is executed as follows. An insulating film is formed on a semiconductor substrate. A first region using the insulating film as a gate insulating film and a second region using another insulating film as a gate insulating film are formed on the semiconductor substrate. The insulating film is protected by a resist film in the first region, and the insulating film is removed by wet etching in the second region. After a semiconductor substrate surface is cleaned by using a sulfuric acid hydrogen peroxide mixture (SPM) or the like as a pre-process, another insulating film having a thickness different from that of the insulating film in the first region is formed in the second region. With this cleaning process, a chemical oxide film adheres to the semiconductor substrate surface in the second region. The chemical oxide film has a thickness of about 10 A. When the thickness of a gate insulating film to be formed in the second region becomes not more than about 1.5 nm and the gate oxide film is formed while remaining the chemical oxide film, a large part of the thin gate insulating film is occupied with low-quality chemical oxide film. Therefore, in order to obtain a high-quality thin gate insulating film, the chemical oxide film needs to be removed. The same adverse affect occurs even though a natural oxide film formed without chemicals is used.

Japanese Unexamined patent publication No. 2000-164861 discloses a method of removing a natural oxide film by using a high-temperature hydrogen gas having a temperature of 750 to 900°.

However, a film removed by the method described in Japanese Unexamined patent publication No. 2000-164861 is a naturally formed oxide film. The method cannot sufficiently remove a chemical oxide film formed by the multi-oxide process. A gate insulating film formed as a result has low quality. Consequently, a high-performance transistor cannot be formed.

On the other hand, when wet etching is performed by a diluted fluorinated acid or the like to remove a chemical oxide film formed by a cleaning process performed after removal of a resist film, the chemical oxide film formed on the semiconductor substrate surface in the second region can be removed. However, at the same time, the insulating film in the first region is disadvantageously etched. In this manner, the insulating film fluctuates in thickness, or damage such as a pin hole occurs in the insulating film. The damage causes the degradation of the electric property such as the time zero dielectric breakdown (TZDB) of an oxide film.

### SUMMARY

In one embodiment, there is provided a method of manufacturing a semiconductor device including: forming a first region in which a first insulating film is formed on a surface of a semiconductor substrate and a second region on which a surface of the semiconductor substrate is exposed; cleaning the surface of the semiconductor substrate exposed in the second region with a cleaning fluid; removing an oxide film formed on the surface of the semiconductor substrate in the second region with the cleaning fluid; forming a second insulating film on the surface of the semiconductor substrate in the second region; forming a gate electrode film on the first insulating film and the second insulating film; and patterning the gate electrode film, the first insulating film, and the second insulating film, wherein, in the removing the oxide film, the oxide film is removed by processing the semiconductor substrate in the presence of a hydrogen gas at a temperature of not less than 940° and not more than 990° and a pressure of not less than 30 Torr and not more than 150 Torr.

In this manner, the cleaning process is performed in the presence of a hydrogen gas in above temperature range and above pressure range, an oxide film serving as a film to be removed is selectively removed, and the insulating film in the first region is not adversely affected. For this reason, according to the method of manufacturing a semiconductor device of the present invention, a desired gate insulating film can be stably obtained even though a multi-oxide process is used, and a semiconductor device having stable transistor characteristics can be provided.

According to the method of manufacturing a semiconductor device of the present invention, a semiconductor device having stable transistor characteristics in use of a multi-oxide process can be obtained.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view typically showing a method of manufacturing a semiconductor device according to an embodiment;

FIG. 2 is a cross-sectional view typically showing a method of manufacturing a semiconductor device according to the embodiment;

FIG. 3 is a cross-sectional view typically showing a method of manufacturing a semiconductor device according to the embodiment;

FIG. 4 is a cross-sectional view typically showing a method of manufacturing a semiconductor device according to the embodiment;

FIG. 5 is a cross-sectional view typically showing a method of manufacturing a semiconductor device according to the embodiment;

FIG. 6 is a cross-sectional view typically showing a method of manufacturing a semiconductor device according to the embodiment;

FIG. 7 is a cross-sectional view typically showing a method of manufacturing a semiconductor device according to the embodiment;

FIG. 8 is a graph showing a relationship among process parameters, chemical oxide film removing capability, and an STI end abnormality in a cleaning process.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

An embodiment of the present invention will be described below with reference to the drawings. In all the drawings, the same reference numerals denote the same constituent elements, the explanation of the constituent elements will not be repeated.

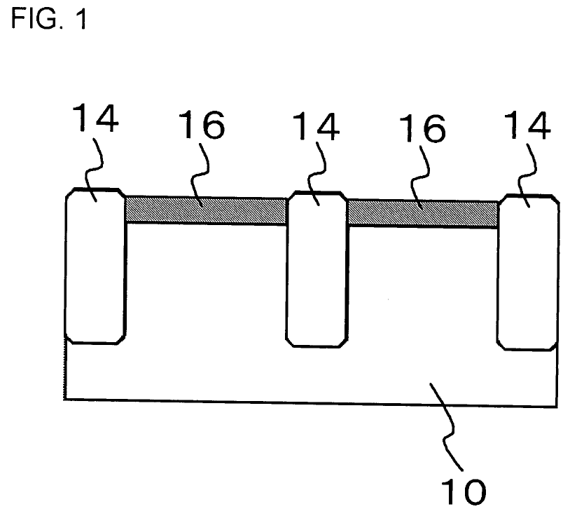

As shown in FIGS. 1 to 7, a method of manufacturing a semiconductor device according to the embodiment includes the following steps.

That is, the method includes the step of forming a first region 20 in which a first insulating film 16 is formed on a surface of a semiconductor substrate 12 and a second region 22 in which a surface of the semiconductor substrate 12 is exposed (FIGS. 1 to 3),

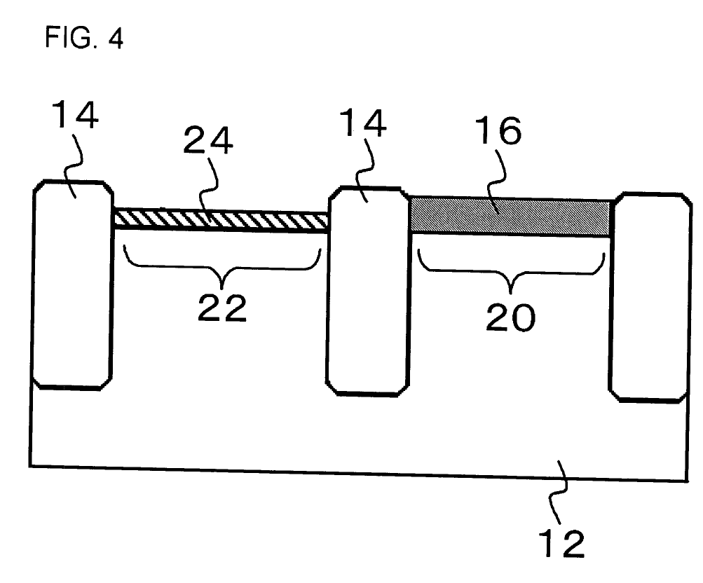

the step of cleaning the surface of the semiconductor substrate 12 exposed in the second region 22 with a cleaning fluid (FIG. 4),

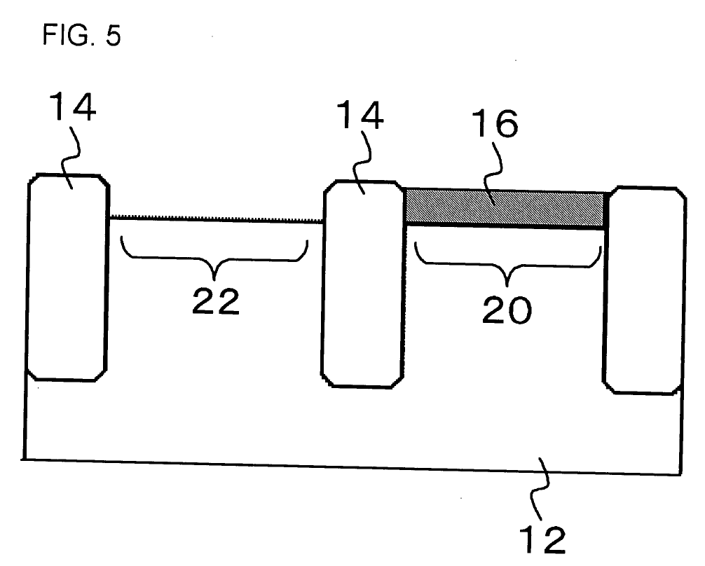

the step of removing a chemical oxide film 24 formed on the surface of the semiconductor substrate 12 in the second region 22 with the cleaning fluid (FIGS. 4 and 5),

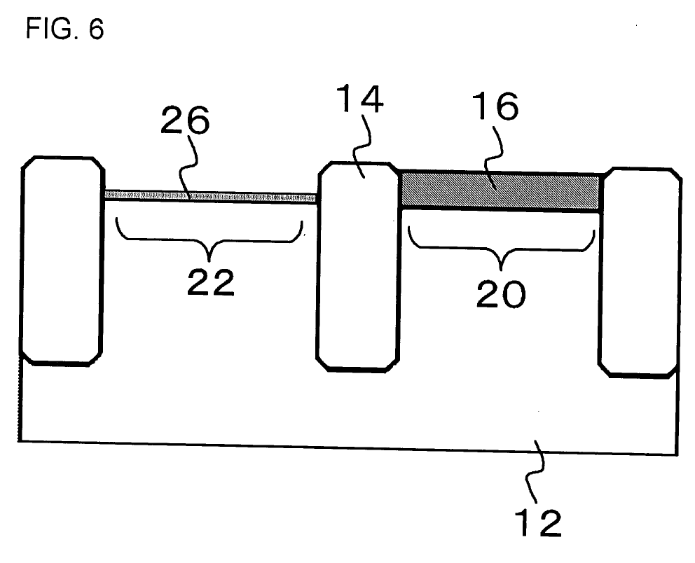

the step of forming a second insulating film 26 having a film thickness different from that of the first insulating film 16 on the surface of the semiconductor substrate 12 in the second region 22 (FIG. 6),

the step of forming a gate electrode film on the first insulating film 16 and the second insulating film 26,

the step of patterning a gate electrode film, the first insulating film 16, and the second insulating film 26, and

the step of forming a first transistor 32 in the first region 20 and forming a second transistor 34 in the second region 22.

The steps of the embodiment will be sequentially described below.

As shown in FIG. 1, an element isolation film 14 is formed on a silicon substrate 10 by a normal method. An impurity is doped in the silicon substrate 10. The silicon substrate 10 is annealed to form a diffusion layer (not shown) of the impurity on a surface layer of the silicon substrate 10. Thereafter, the first insulating film 16 is formed on the diffusion layer by thermal oxidation (FIG. 1).

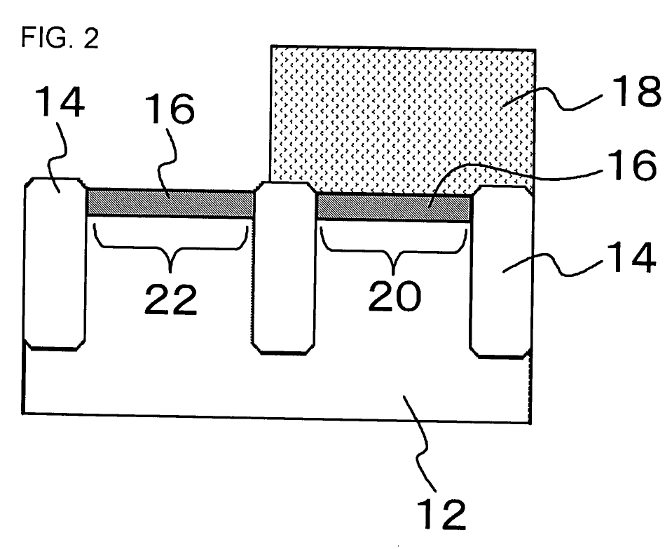

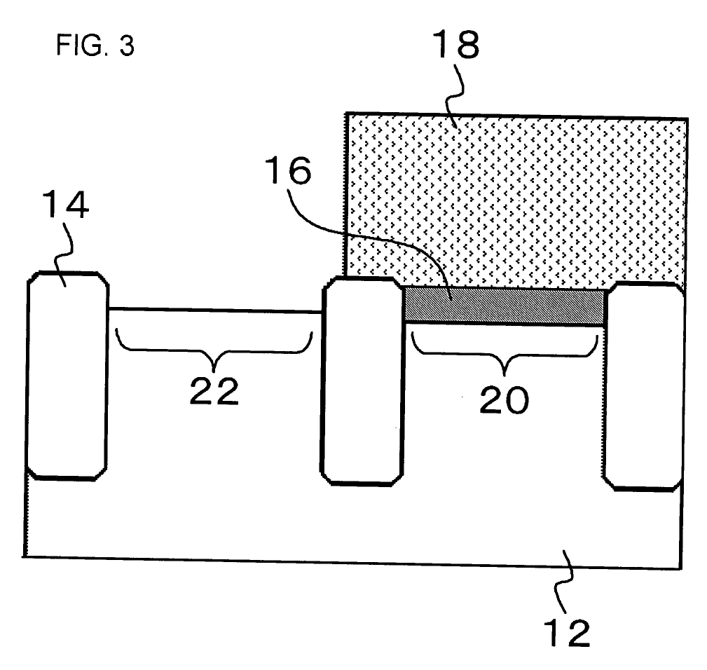

The first region 20 is protected by a resist film 18 (FIG. 2). The first insulating film 16 in the second region 22 is removed by wet etching (FIG. 3). The first region 20 is an expected region in which a transistor element having a film thickness (electric film thickness) larger than that in the second region 22 is to be formed.

Thereafter, the resist film 18 in the first region 20 is removed, the surface of the semiconductor substrate 12 exposed in the second region 22 is cleaned with a predetermined cleaning fluid as a pre-process (FIG. 4).

The surface of the semiconductor substrate 12 is cleaned by an ordinary method. As the cleaning fluid, a sulfuric acid hydrogen peroxide mixture (SPM), a hydrofluoric acid hydrogen peroxide mixture (FPM), a hydrochloric acid hydrogen peroxide mixture (HPM), or an ammonia hydrogen peroxide mixture (APM) can be used.

In this cleaning step, the chemical oxide film 24 is formed on the surface of the semiconductor substrate 12 exposed in the second region 22. The chemical oxide film 24 has a film thickness of about 10 Angstrom, and must be removed when a thin gate insulating film is formed in the second region 22.

Therefore, in order to remove the chemical oxide film 24, the semiconductor substrate 12 is processed in the presence of a hydrogen gas under conditions: temperatures of not less than 940° C. and not more than 990° C., preferably, not less than 960° C. and not more than 980° C.; and pressures of not less than 30 Torr and not more than 150 Torr, preferably, not less than 50 Torr and not more than 150 Torr. When the semiconductor substrate 12 is processed under the conditions, the chemical oxide film 24 in the second region 22 can be selectively removed by etching with respect to the first insulating film 16 serving as a thermal oxide film (FIG. 5). Combinations between the temperature ranges and the pressure ranges may be arbitrarily used.

A flow rate of a hydrogen gas used when the chemical oxide film 24 is removed is set at 5 to 50 SLM.

The above step of removing the chemical oxide film 24 can also be performed in a reduced-pressure processing apparatus such as a reduced-pressure RTP apparatus.

The second insulating film 26 is formed on the surface of the semiconductor substrate 12 of the second region 22 (FIG. 6). The second insulating film 26 can be formed by thermal oxidation or thermal nitridation. The second insulating film 26 is formed to have a film thickness (electric film thickness) smaller than that of the first insulating film 16. The first insulating film 16 in the first region increases by the thermal oxidation or thermal nitridation. However, an increasing amount is normally little.

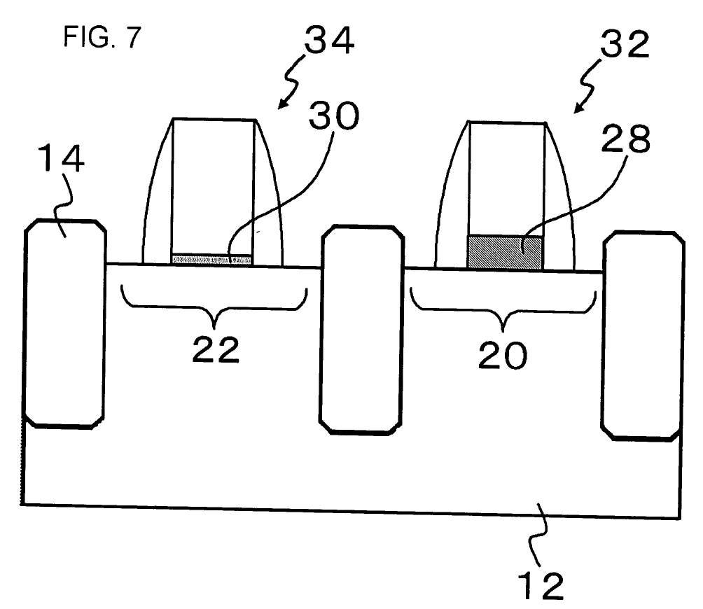

According to the ordinary method, a gate electrode film, patterning to a gate electrode (and a gate insulating film thereunder), side walls on both the sides of the gate electrode, and the like are sequentially formed to form the first transistor 32 in the first region 20. The second transistor 34 is formed in the second region 22 (FIG. 7).

An effect in the embodiment will be described below.

In the embodiment, in the presence of a hydrogen gas, a semiconductor substrate is processed at temperatures of not less than 940 degree C. and not more than 990 degree C. and pressures of not less than 30 Torr and not more than 150 Torr.

The semiconductor substrate is processed under the conditions to selectively remove the chemical oxide film 24 serving as a film to be removed not to adversely affect the first insulating film 16 in the first region 20. For this reason, according to the embodiment of a semiconductor device according to the embodiment, a desired gate insulating film can be stably obtained even though a multi-oxide process is used, so that stable transistor characteristics can be obtained. Therefore, a yield of semiconductor devices increases.

When the present inventor devotedly researched conditions to remove the chemical oxide film 24, the present inventor founds a novel problem in which, depending on process conditions (temperature and pressure), Si is migrated to moderate stress at an end of the element isolation film 14 on the diffusion layer so as to form an uneven shape at the end of the element isolation film 14.

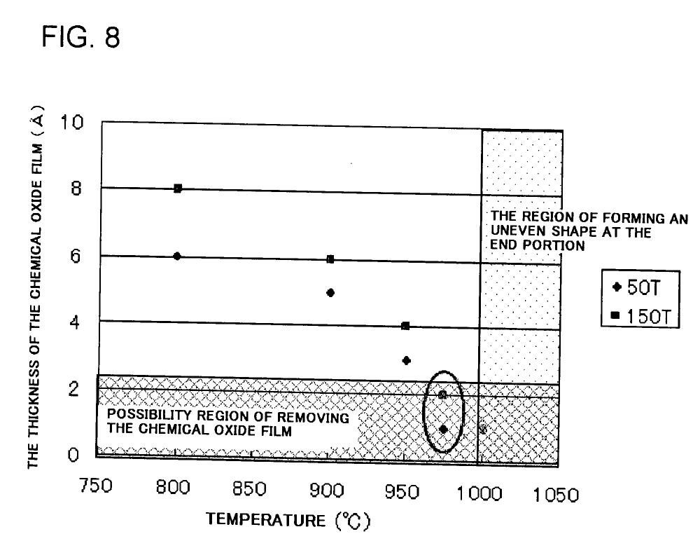

Therefore, the present inventor, as shown in FIG. 8, set pressures of 50 Torr and 150 Torr and temperatures of 800° C., 900° C., 950° C., and 975° C. and examined a relationship between a removable range of the chemical oxide film 24 and the uneven shape at the end of the element isolation film 14. The examination was performed at a hydrogen gas flow rate of 20 SLM. As a result, when a higher temperature or a lower pressure was set as the process conditions, the uneven shape at the end of the element isolation film 14 was conspicuous. It was found that the uneven shape was easily formed under conditions which capability of chemical oxide film removing with hydrogen gas was high.

On the basis of the knowledge, the relationship was further examined. In the presence of a hydrogen gas, under conditions: temperatures of not less than 940 and not more than 990 degree C., preferably, not less than 960 and not more than 980 degree C.; and pressures of not less than 30 and not more than 150 Torr, preferably not less than 50 and not more than 150 Torr, it was further found that both removal of the chemical oxide film 24 and suppression of the uneven shape at the end of the element isolation film 14 were excellent.

More specifically, by the cleaning step of the embodiment, a desired gate insulating film can be stably obtained, and an uneven shape at the end of the element isolation film 14 is suppressed. For this reason, a semiconductor device having more stable transistor characteristics can be provided.

Furthermore, hydrogen gas treatment is performed to make it possible to selectively etch the chemical oxide film 24. In this manner, the chemical oxide film 24 can be removed as a pre-process of the second insulating film 26 without damaging the first insulating film 16. Therefore, in both the regions, semiconductor devices having excellent transistor characteristics can be obtained.

During the hydrogen gas treatment, hydrogen-terminated Si with on the surface of the diffusion layer is migrated to improve the degree of planarization of the diffusion layer, and transistor characteristics are advantageously improved.

Furthermore, the step of forming the second insulating film 26 can be continuously performed in the reduced-pressure processing apparatus used in the step of removing the chemical oxide film 24.

In this manner, organic matters or the like can be suppressed from adhering to the region of the semiconductor substrate surface on which the gate insulating film is formed, and reliability of the transistor and uniformity of gate insulating film thicknesses can be improved.

The embodiments of the present invention have been described above with reference to the accompanying drawings. However, the embodiments of the present invention are examples of the present invention. Various configurations except for the above configurations can also be employed.

The first region 20 and the second region 22 are not necessarily adjacent to each other, and another region may be present between the first region 20 and the second region 22.

It is apparent that the present invention is not limited to the above embodiment, and may be modified and changed without departing from the scope and spirit of the invention.

What is claimed is:

1. A method of manufacturing a semiconductor device comprising:
forming a first region in which a first insulating film is formed on a surface of a semiconductor substrate and a second region on which a surface of said semiconductor substrate is exposed;
cleaning said surface of said semiconductor substrate exposed in said second region with a cleaning fluid;
removing an oxide film formed on said surface of said semiconductor substrate in said second region with said cleaning fluid;
forming a second insulating film on said surface of said semiconductor substrate in said second region;
forming a gate electrode film on said first insulating film and said second insulating film; and
patterning said gate electrode film, said first insulating film, and said second insulating film, wherein
in said removing said oxide film, said oxide film is removed by processing said semiconductor substrate in the presence of a hydrogen gas at a temperature of not less than 940° and not more than 990° and a pressure of not less than 30 Torr and not more than 150 Torr.

2. The method according to claim 1, wherein
said removing said oxide film is performed in a reduced-pressure processing apparatus.

3. The method according to claim 1, wherein
said forming said second insulating film is continuously performed in said reduced-pressure processing apparatus used in said removing said oxide film.

4. The method according to claim 1, wherein
said cleaning fluid is one of a sulfuric acid hydrogen peroxide mixture (SPM), a hydrofluoric acid hydrogen peroxide mixture (FPM), a hydrochloric acid hydrogen peroxide mixture (HPM), and an ammonia hydrogen peroxide mixture (APM).

5. The method according to claim 1, wherein
said forming said second insulating film includes
forming a second insulating film having a film thickness different from that of said first insulating film on said semiconductor substrate surface in said second region.
